(19) United States
(12) Patent Application Publication
(10) Pub. No.: US 2014/0292152 A1
(43) Pub. Date: Oct. 2, 2014

(54) TEMPERATURE COMPENSATING ELECTRODES

(71) Applicant: Cymatics Laboratories Corp., Pittsburgh, PA (US)

(72) Inventors: Peter Ledel Gammel, Millburn, NJ (US); Marco Mastrapasqua, Annandale, NJ (US); Hugo Safar, Westfield, NJ (US); Rajarishi Sinha, Pittsburgh, PA (US)

(73) Assignee: Cymatics Laboratories Corp., Pittsburgh, PA (US)

(21) Appl. No.: 14/230,155

(22) Filed: Mar. 31, 2014

Related U.S. Application Data
(60) Provisional application No. 61/807,100, filed on Apr. 1, 2013.

(51) Int. Cl. H01L 41/047

(52) U.S. Cl. CPC H01L 41/0477
USPC 310/346

(57) ABSTRACT

A resonator device in which a piezoelectric material is disposed between two electrodes. At least one of the electrodes is formed of a nickel-titanium alloy having equal portions nickel and titanium.

### FIELD OF THE INVENTION

This application claims the benefit of the filing date of U.S. Provisional Patent Application No. 61/807,100 filed Apr. 1, 2013, the disclosure of which is hereby incorporated herein by reference.

### BACKGROUND OF THE INVENTION

RF timing and certain filtering applications require a high degree of stability despite temperature changes. The frequency of a clock generator, or the response of a filter should not be affected by a change in operating temperature. The temperature stability requirement is specified as a frequency shift budget, expressed as part-per-million per degrees Kelvin (ppm/° K).

Acoustic devices, such as BAW (FBAR and SMR) resonators and filters, suffer from temperature variation in their response and main parameters, due to changes in material properties (e.g. speed of sound, volume, etc.) with temperature. These response variations need to be compensated in order to achieve temperature-stable circuits.

The resonance frequency of a BAW resonator is set by the length of the acoustic path. The acoustic path depends on the acoustic velocities and thicknesses and geometry of the constituent thin film materials. Unless compensated, variations such as those described above can cause the resonance frequency of the BAW resonator to vary with temperature.

A common temperature compensation technique consists in fabricating a silicon oxide (SiO₂) layer in the BAW resonator stack. This and similar temperature compensation techniques are detrimental to fabrication time and cost, and to device performance. Therefore, temperature compensation device structures and fabrication techniques that reduce processing time and improve device performance continue to be sought.

### BRIEF SUMMARY OF THE INVENTION

Described herein are BAW resonators and similar devices that have metal electrodes, at least one of which is a metal alloy. The metal alloy has a temperature dependent material property (e.g. coefficient of thermal expansion or TCE) that is opposite of, and therefore compensates for, the temperature dependence of another constituent of the device (such as the acoustic active material). For example, certain alloys formed by combining Nickel (Ni) and Titanium (Ti) have the desired thermally dependent material property. Using these materials for electrodes in a BAW resonator can reduce the resonator's temperature drift.

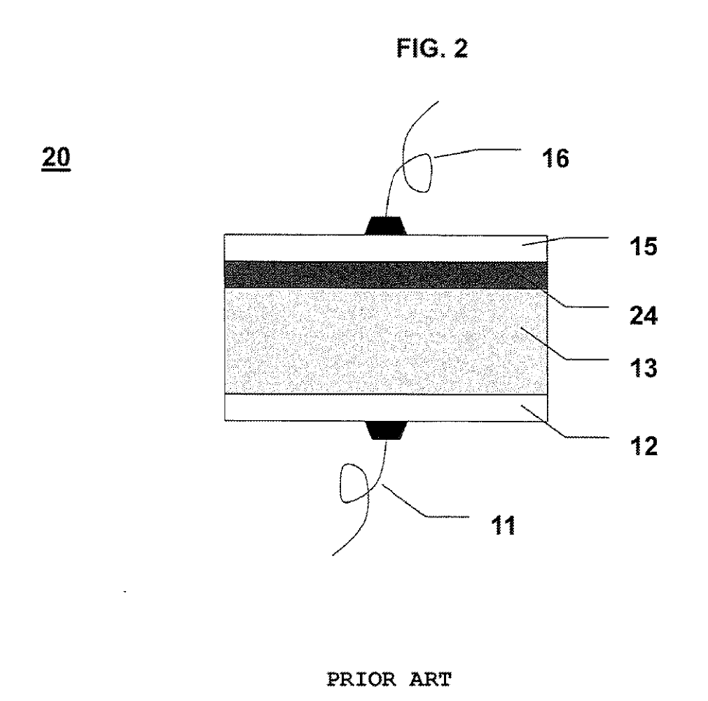

One embodiment of the present invention uses equiatomic Nickel-Titanium (50:50 NiTi; referred to as “NiTi”) for at least one of the electrodes. NiTi has a positive temperature coefficient of elastic modulus over a range of temperatures, starting at a little below room temperature (270° K) and extending beyond 350° K. This is illustrated in FIG. 2 of Matsumoto, H., “Positive temperature coefficient of elastic modulus in the high-temperature phase of NiTi,” J. Mat. Sci. Letters, 13, pp. 955-956 (1994). NiTi is commercially available from Nitinol Devices & Components, Inc. as Nitinol™.

The melting point of NiTi is about 1450° C. NiTi has a density of about 6465 kg/m³. NiTi can be sputter deposited on silicon substrates using DC magnetron sputtering. A NiTi target in the presence of a low-pressure argon plasma is used as a source for NiTi material. Upon deposition on to the silicon wafer, the NiTi film is amorphous. It is then crystallized by annealing to obtain the desired properties. SiO₂ and chromium are contemplated for use as barrier layers to prevent the migration of Ni and Ti ions into other layers in the resonator.

NiTi has been shown to have a thermoelastic martensitic transformation (characteristic of shape-changing alloys). In the high temperature phase, an elastic anomaly has been observed. In this phase, the elastic modulus has been observed to increase with an increase in temperature. Because the property increases with increasing temperature, NiTi has a positive temperature coefficient of elastic modulus (TCE). Therefore, NiTi can compensate the temperature drift of BAW resonators that have a negative native temperature drift.

NiTi, being a conductive alloy, also performs the charge collection function that is normally performed by the resonator electrodes. Using NiTi as electrode material simplifies the manufacturing flow because it alleviates the need for another temperature compensation technique, and has a small positive benefit to the k². However, the resistivity of NiTi can be a magnitude higher than other resonator electrode materials such as W, Mo, Ru, Ir, etc. This can cause an unacceptable reduction in the series quality factor. Therefore, a NiTi-based resonator is particularly suitable for applications where the resonator operates at very low impedance, such as oscillators that operate around the parallel resonance of the resonator.

The NiTi is preferably placed as close to the anti-nodal points of the dominant mode as possible, given the manufacturing process. This is so that the NiTi layer is subject to maximum strain. This can permit the resonator designer to use a thinner layer of NiTi.

Conversely, the NiTi can be moved away from the anti-nodal points, with a commensurate decrease in the strain that it experiences. This would require the resonator designer to use a thicker layer of NiTi. Thicker layers can be easier to manufacture, but can also cause a small decrease in the k².

BAW resonators with NiTi electrodes improve upon BAW resonators known in the prior art in three ways. First, the invention provides improved k² because the absence of the SiO₂ dielectric film in the resonator circuit raises the k². Second, the NiTi electrodes provide a resonator with an improved Q because NiTi is less acoustically lossy than SiO₂, so the removal of SiO₂ and substitution by NiTi has a net effect of raising the Q factor of the resonator. Third, the resonator is easier to manufacture because thickness control requirements are more relaxed for a NiTi electrode layer than for a SiO₂ temperature compensation layer.

A complete understanding of the present invention may be obtained by reference to the accompanying drawings, when considered in conjunction with the subsequent, detailed description, in which:

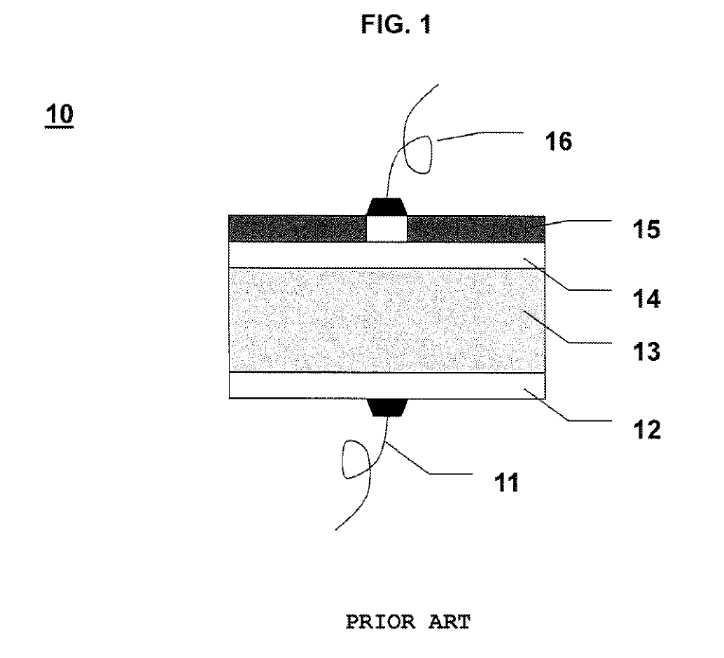

FIG. 1 is a schematic view of a bulk-acoustic wave resonator from the prior art.

FIG. 2 is a schematic view of a bulk-acoustic wave resonator from the prior art.

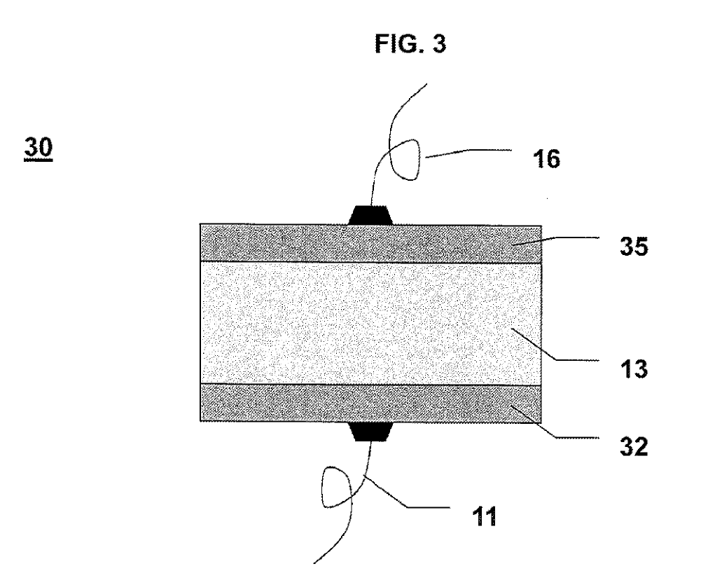

FIG. 3 is a schematic view of a bulk-acoustic wave resonator with temperature drift compensating electrodes of the present invention.

For purposes of clarity and brevity, like elements and components will bear the same designations and numbering throughout the Figures.

### DETAILED DESCRIPTION

This invention reduces the temperature sensitivity of BAW resonators without some of the drawbacks of temperature compensation techniques that are present in prior art resonators.

In prior art BAW resonators, the reduction in temperature sensitivity has been achieved through active and/or passive means. Active means include circuit elements that adjust the resonator frequency response by switching inductances and/or capacitances into and out of circuit. All such schemes require power to operate. These schemes can also be lossy, and the nonlinearity of the switch can cause errors.

Passive means include incorporating materials into the resonator that have temperature coefficients that are positive, to cancel the negative temperature coefficients of most commonly used resonator materials. In AlN-based BAW resonators, SiO₂ heretofore has been widely used as the temperature compensating material in the resonator stack. This is because its temperature coefficient of stiffness is a large positive value, typically between +70 to +85 ppm/K. Since SiO₂ is a commonly available semiconductor material, it is very often the temperature compensating material of choice.

In prior art BAW resonators, the presence of a dielectric material such as SiO₂ in the resonator effectively forms a capacitor in series with the resonator, which decreases the electromechanical coupling coefficient k².

In prior art BAW resonators, the temperature-compensation layer does not have any purpose other than temperature compensation, and otherwise decreases the device's performance by mechanical loading and/or added parasitic capacitance. Acoustic losses in a material are known to have an inverse cubic relationship with acoustic velocity. As a result, several researchers have experimentally shown that adding SiO₂ to an AlN SMR resonator reduces its quality factor by about 30%.

In prior art BAW resonators, adding a temperature-compensation layer to the resonator stack increases process complexity and time. For a SMR resonator operating in the 1-3 GHz range, only very thin (i.e. less than 100 nanometers) of SiO₂ is required. Depositing such a thin layer with within-wafer and cross-wafer thickness control is a challenging task. Errors manifest as yield loss in the process flow.

FIG. 1 is a schematic view of a bulk-acoustic wave (BAW) resonator 10 from the prior art. The configuration shown is a thickness-extensional mode film bulk-acoustic resonator (FBAR). The acoustic isolation structures are not illustrated. The piezoelectric (e.g. AlN) layer 13 is formed on the bottom electrode 12. The temperature compensating material 15 is SiO₂, and is illustrated as placed on top of the upper electrode 14. The bottom connector 11 and the top connector 16 connect the resonator to an electrical circuit.

FIG. 2 is a schematic view of a bulk-acoustic wave (BAW) resonator 20 from the prior art. The configuration shown is also a thickness-extensional mode film bulk-acoustic resonator (FBAR). The acoustic isolation structures are not illustrated. The piezoelectric (e.g. AlN) layer 13 is formed on the bottom electrode 12. The temperature compensating material 15 is SiO₂, which is placed under the upper electrode 14. The bottom connector 11 and the top connector 16 connect the resonator to an electrical circuit.

FIG. 3 is a schematic view of a bulk-acoustic wave (BAW) resonator 30 according to one embodiment of the present invention. The resonator 30 has temperature drift compensating electrodes 32 and 35. The illustrated configuration is a thickness-extensional mode film bulk-acoustic resonator (FBAR). The acoustic isolation structures are not illustrated. The piezoelectric (e.g. AlN) layer 13 is formed on the bottom electrode 32. The upper electrode 35 and lower electrode 32 perform both the temperature-compensation function and the charge collection function. The bottom connector 11 and the top connector 16 connect the resonator to an electrical circuit.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A bulk acoustic wave resonator device operating in the thickness extensional mode having at least a first bottom electrode and second top electrode and a piezoelectric material interposed therebetween wherein at least one of the first bottom electrode and the second top electrode are formed of a nickel-titanium alloy having equal portions nickel and titanium.
